(19) United States
(12) Patent Application Publication
(10) Pub. No.: US 2021/0402701 A1
(43) Pub. Date: Dec. 30, 2021

(54) SYSTEMS AND METHODS OF HIERARCHICAL MATERIAL DESIGN FOR ADDITIVE FABRICATION

(71) Applicant: Massachusetts Institute of Technology, Cambridge, MA (US)

(72) Inventors: Kiril Vidimce, Cambridge, MA (US); Ye Wang, San Francisco, CA (US); Wojciech Matusik, Lexington, MA (US)

(21) Appl. No.: 17/208,261

(22) Filed: Mar. 22, 2021

Related U.S. Application Data
(63) Continuation of application No. 16/507,693, filed on Jul. 10, 2019, now abandoned.
Application No. 16/507,693 is a continuation of application No. 14/568,057, filed on Dec. 11, 2014, now abandoned.

(51) Int. Cl. B29C 64/386; G06F 30/00

(52) U.S. Cl. CPC B29C 64/386; B29K 2055/02; G06F 30/00

(57) ABSTRACT

According to some aspects, a method of designing a three-dimensional object based on a shape of the object, the object to be fabricated via additive fabrication from a plurality of materials, is provided. The method comprises selecting, for a first volume element of the object, one of the plurality of materials based at least in part on a position of the first volume element within the object, at least one spatial decomposition of the object, the at least one spatial decomposition identifying a plurality of volumetric subregions of the object, and a material composition of at least a first volumetric subregion of the plurality of volumetric subregions, wherein the first volumetric subregion comprises the position of the first volume element.

### STATEMENT REGARDING FEDERALLY SPONSORED RESEARCH OR DEVELOPMENT

This invention was made with government support under Grant No. CBET-0952564 awarded by the National Science Foundation. The government has certain rights in this invention.

### BACKGROUND

Additive fabrication, e.g., 3-dimensional (3D) printing, provides techniques for fabricating objects, typically by causing portions of a building material to solidify and/or combine at specific locations. Additive fabrication techniques may include stereolithography, selective or fused deposition modeling, direct composite manufacturing, laminated object manufacturing, selective phase area deposition, multi-phase jet solidification, ballistic particle manufacturing, particle deposition, laser sintering, polyjet, or combinations thereof. Many additive fabrication techniques build parts by forming successive layers, which are typically cross-sections of the desired object. Typically each layer is formed such that it adheres to either a previously formed layer or a substrate upon which the object is built.

### SUMMARY

According to some aspects, a method is provided of designing a three-dimensional object based on a shape of the object, the object to be fabricated via additive fabrication from a plurality of materials, comprising selecting, for a first volume element of the object, one of the plurality of materials based at least in part on a position of the first volume element within the object, at least one spatial decomposition of the object, the at least one spatial decomposition identifying a plurality of volumetric subregions of the object, and a material composition of at least a first volumetric subregion of the plurality of volumetric subregions, wherein the first volumetric subregion comprises the position of the first volume element.

According to some aspects, at least one computer-readable medium is provided comprising instructions that, when executed, perform a method of designing a three-dimensional object based on a shape of the object, the object to be fabricated via additive fabrication from a plurality of materials, the method comprising selecting, for a first volume element of the object, one of the plurality of materials based at least in part on a position of the first volume element within the object, at least one spatial decomposition of the object, the at least one spatial decomposition identifying a plurality of volumetric subregions of the object, and a material composition of at least a first volumetric subregion of the plurality of volumetric subregions, wherein the first volumetric subregion comprises the position of the first volume element.

According to some aspects, a system is provided for designing a three-dimensional object based on a shape of the object, the object to be fabricated via additive fabrication from a plurality of materials, the system comprising at least one processor configured to select, for a first volume element of the object, one of the plurality of materials based at least in part on a position of the first volume element within the object, at least one spatial decomposition of the object, the at least one spatial decomposition identifying a plurality of volumetric subregions of the object, and a material composition of at least a first volumetric subregion of the plurality of volumetric subregions, wherein the first volumetric subregion comprises the position of the first volume element.

The foregoing summary is provided by way of illustration and is not intended to be limiting.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 depicts an illustrative method of selecting a material for a volume element of an object based on a hierarchical design scheme, according to some embodiments;

FIG. 2 depicts an operator suitable for use within a hierarchical design scheme, according to some embodiments;

FIG. 3 depicts an illustrative hierarchical design scheme that decomposes an object based on a plane operator, according to some embodiments;

FIG. 4 depicts an illustrative hierarchical design scheme that decomposes an object based on a radial stratum operator, according to some embodiments;

FIGS. 5A-B depict an illustrative graphical user interface suitable for practicing some embodiments of the invention;

FIGS. 6A-C depict steps of an illustrative process in which the material composition of a teddy bear is designed using a hierarchical design scheme, according to some embodiments;

FIG. 7A depicts an illustrative three-dimensional shape used in the design of a tweel object, according to some embodiments;

FIG. 7B and FIG. 7D depict portions of an illustrative hierarchical design scheme used to design a tweel object, according to some embodiments;

FIGS. 7C and E are photographs of a fabricated tweel described by the hierarchical design scheme of FIGS. 7B and 7D and using the three-dimensional shape shown in FIG. 7A, according to some embodiments;

FIG. 8 depicts a system suitable for practicing aspects of the invention, according to some embodiments; and

FIG. 9 illustrates an example of a computing system environment on which aspects of the invention may be implemented.

### DETAILED DESCRIPTION

Some additive fabrication techniques allow an object to be fabricated from more than one material. In order to instruct an additive fabrication device to fabricate an object from multiple materials, the device needs to be told which of the materials to place in each location within the object. An additive fabrication device is generally capable of repeatedly forming material within a series of small volumes, and produces an object by sequentially forming material in adjacent such volumes (e.g., by sequentially producing layers of such volumes, or otherwise). Typically, a volume in which material may be formed by an additive fabrication device is referred to as a “volume element,” or a “voxel.” To direct an additive fabrication device to form an object, therefore, effectively comprises indicating to the device which material to form in each voxel. One way to do this is to select, for each individual voxel, a material to form in that voxel. However, for most additive fabrication devices, this would necessitate a material specification for tens or hundreds of billions of voxels. For a user wishing to design an object to be made from multiple materials, building a specification of this type may be impractical.

Alternatively, a user may specify the boundaries and positions of a number of volumes that are each to be filled with one of the materials. Some combination of software and the additive fabrication device can identify which voxels are located in each volume and determine which material to form in each volume. The object may then be fabricated by forming the specified material in the voxels in each volume. As the number of such material-filled volumes increases, however, it becomes more and more cumbersome to define the shape of each volume. In addition, since an object is formed from the collection of volumes, each volume must be positioned and shaped to fit together with the other volumes so that the object is formed with the volumes connected to one another.

The inventors have recognized and appreciated that a material composition of an object may be produced by using a hierarchical design scheme that decomposes the object into subregions. A hierarchical design scheme that decomposes the object into subregions may allow for specification of a material for each voxel in an object, but in such a way that allows a user to easily design the composition of the object and which may be described by a comparatively small number of parameters. Additionally, since the object is spatially decomposed, a user need not be concerned with ensuring that the identified subregions fit together, as this will occur naturally as part of the design process. Accordingly, a material composition that would be cumbersome or impossible to specify by directly specifying the material in each voxel, or in each of a number of volumes, may be readily described.

According to some embodiments, a hierarchical design scheme may specify one or more spatial decompositions that divide an object into subregions (e.g., volumes). Spatial decompositions may also be applied to a subregion identified by another spatial decomposition, such that an object may be successively divided into a number of subregions by specifying a collection of spatial decompositions. In this case, the hierarchical design scheme may have the form of a tree or graph structure. By navigating the graph for a given location within the object, the hierarchical design scheme may produce an answer to the following question: what material should be formed in this location?

According to some embodiments, a hierarchical design scheme may specify one or more material compositions to be formed within a particular subregion (e.g., a subregion identified by a spatial decomposition). This indicates that the subregion is to be filled with the specified material composition. As described above, an object may be repeatedly divided into subregions by spatial decompositions. A material composition may be specified for each of the smallest identified subregions, thereby specifying how the object is to be formed.

According to some embodiments, a heterogeneous material composition may be specified for a volumetric subregion. While, in some cases, a volumetric subregion may comprise a homogenous material (i.e., a subregion comprising only a single material produced by an additive fabrication device), there may be benefits for a material composition to instead vary within the subregion. For example, subregions that comprise formations of multiple materials produced by an additive fabrication device may be used to produce objects with complex properties. A heterogeneous material composition may vary across a region based on a gradient or by interpolation, such that heterogeneous features of a material composition may vary in size and/or shape within a single subregion. Examples of such features are discussed below.

According to some embodiments, a hierarchical design scheme may include one or more spatial decompositions that separate a space into two or more volumetric subregions in a way that is mathematically describable. In which of the subregions, if any, a three-dimensional location is located may therefore be determined by evaluating a mathematical formula (e.g., an inequality). When the location is that of a voxel, therefore, the voxel's presence in one of the subregions may be determined. If the determined subregion is associated with a further spatial decomposition, this process may be repeated until a material specification is identified for a subregion.

According to some embodiments, a hierarchical design scheme may include a spatial decomposition that is based on one or more distance queries. A decomposition may, for example, be based on a distance from a surface (e.g., the surface of the object), a curve or a point. Distance query-based spatial decompositions may allow for the decomposition of an object to be specified in a way that is independent of the shape of the object. A spatial decomposition based on a distance to the surface of an object, for example, may decompose the object into a “skin” layer and an interior layer, which may be applied to an object of any shape.

According to some embodiments, a first hierarchical design scheme may be used as a meta operator within a second hierarchical design scheme. Once a hierarchical design scheme has been defined that, for example, performs spatial decompositions and/or defines material compositions, this scheme may be turned into a meta operator to be used in the design of any subsequent hierarchical design schemes. In this case, a user may specify inputs and outputs of the meta operator that map to inputs and outputs of operators within the meta operator's hierarchy. A library of hierarchical design schemes may, in some cases, be available such that users may access any design scheme previously produced and apply it to a design at hand, as appropriate.

Following below are more detailed descriptions of various concepts related to, and embodiments of, hierarchical design schemes that decompose an object into subregions. It should be appreciated that various aspects described herein may be implemented in any of numerous ways. Examples of specific implementations are provided herein for illustrative purposes only. In addition, the various aspects described in the embodiments below may be used alone or in any combination, and are not limited to the combinations explicitly described herein.

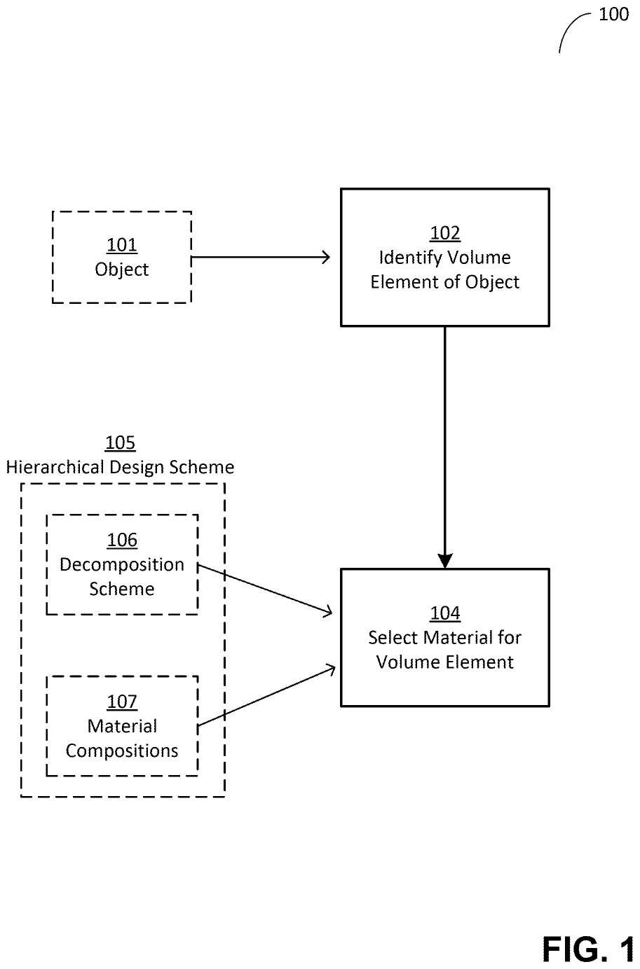

As discussed above, a hierarchical design scheme may indicate, for a volume element of an object, which material to form in that volume element. The material composition of the whole object may thereby be determined by determining a material in this way for each volume element of the object. FIG. 1 depicts an illustrative method of selecting a material for a volume element of an object based on a hierarchical design scheme, according to some embodiments. In method 100, a volume element of an object 101 is identified, and based on a hierarchical design scheme, a material is selected for that volume element. Method 100 may be performed for all of the volume elements of the object to determine the material composition of the object, and may be performed in serial (i.e. perform method 100 for each volume element one after another) or in parallel (i.e., perform method 100 for at least two volume elements simultaneously). Additive fabrication of object 101 may then be performed once method 100 has been performed for some, or all, of the volume elements of the object.

Object 101 may comprise any suitable description of an object, such as a description of the shape of the object, which may be mathematical in nature and/or may comprise a description of a plurality of polygons that together describe the shape of the object. For example, object 101 may be described by a collection of vertices and normal vectors that define polygons (e.g., in a STereoLithography (STL) file). According to some embodiments, the object may be described by a closed surface.

In act 102, a volume element of object 101 is identified. The volume element may have any suitable size and shape, and in some cases may have a size and shape dependent on an additive fabrication device which is to be used to fabricate object 101. For example, the resolution of an additive fabrication device (the minimum volume in which material may be formed) may dictate, at least in part, the size and/or shape of the volume element. In some cases, the volume element has a cuboidal shape and measures between 1 μm and 100 μm along each side (e.g., measures 40 μm by 80 μm by 30 μm).

As described above, method 100 may be performed for each volume element in object 101, in which case the volume element may be identified in act 102 in the usual course of performing the method for each volume element (e.g., in a sequence). Additionally, or alternatively, the volume element may be identified based on its position within the object (e.g., in a particular layer of volume elements). For example, a material for each volume element in a bottom layer of the object may be determined before other volume elements are identified (e.g., so that an additive fabrication device may begin fabrication with the bottom layer) and the volume element may accordingly be identified in act 102 so as to be in the bottom layer. Where method 100 is performed multiple times for volume elements of object 101, not all volume elements identified in act 102 need be the same size or shape, as some additive fabrication devices may be instructed to form material in volume elements that have a range of sizes and/or shapes.

In act 104, a material is selected for the volume element identified in act 102. The selection of the material is based at least in part on decomposition scheme 106 and material compositions 107, which are aspects of hierarchical design scheme 105. As discussed above, a hierarchical design scheme may perform one or more spatial decompositions and may further indicate a material composition for each volumetric subregion identified by the spatial decompositions. As such, these spatial decompositions may be described by decomposition scheme 106, and the material compositions for the resulting volumetric subregions may be described by material compositions 107. Hierarchical design scheme 105 may additionally include other aspects, such as coordinate remappings or texture applications, examples of which are discussed below.

According to some embodiments, hierarchical design scheme 105 may be described by a directed acyclic graph. The graph may include one or more decomposition nodes that identify volumetric subregions of a volume according to decomposition scheme 106, and/or may include nodes that specify a material composition of an identified subregions according to material compositions 107. Operations performed by a node of the graph, whether it be identification of volumetric subregions, identification of a material composition, and/or a different operation, may be parameterized by any number of parameters. The hierarchical design scheme may thereby be described by the set of parameters that define the operations of the nodes of the graph.

Decomposition scheme 106 may include any number of operators that identify a plurality of volumetric subregions of a volumetric region. As discussed above, where hierarchical design scheme 105 is described by a graph or tree structure, one or more spatial decompositions may be performed based on a volumetric subregion identified by another spatial decomposition. For example, decomposition scheme 106 may identify a first plurality of volumetric subregions of object 101 using a first spatial decomposition. A second spatial decomposition may then identify a second plurality of volumetric subregions within one of the first plurality of volumetric subregions. Decomposition scheme 106 may “chain” together any number of such operations in this way.

Material compositions 107 may include any number of homogeneous and/or heterogeneous material compositions. The material(s) chosen for each material composition may include any material(s) suitable for additive fabrication. In some cases, a material for a material composition (which may be homogeneous or heterogeneous) may be chosen based on the type of additive fabrication technique and/or device being used. For example, a list of materials available to an additive fabrication device for forming objects may be determined and used, at least in part, to select material compositions 107. Such materials may include, but are not limited to, one or more thermoplastics (e.g., PLA, ABS, etc.), rubber, metal alloys, photopolymers, silicone, nylon, HDPE, or combinations thereof. A list of materials may identify two materials that are identical but for differences in pigmentation (e.g., different pigments or the presence of a pigment versus the absence of any added pigmentation).

According to some embodiments, material compositions 107 may include one or more material compositions that comprise a void material, which indicates empty space is to be formed. In some cases, it may be desirable not to form any material in certain locations within object 101. For instance, in forming a material that contains holes at the surface and/or within its interior (e.g., a material like sponge or Swiss cheese), it may be beneficial to treat empty space as a material composition that may be chosen for a given volume element, just as any other material may be chosen. Material compositions 107 may therefore include a homogeneous void material, and/or a heterogeneous material composition in which one or more materials used to produce the heterogeneous structure is the void material.

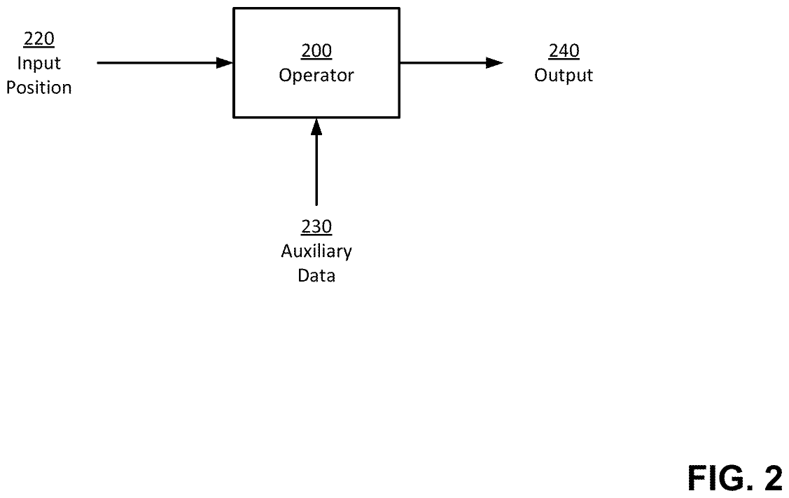

As discussed above, a hierarchical design scheme may include one or more operators that, for example, identify a volumetric subregion and/or a material for a position within an object. FIG. 2 depicts an illustrative operator suitable for use in a hierarchical design scheme, according to some embodiments. Operator 200 may perform any suitable operation within a hierarchical design scheme including, but not limited to: identifying a volumetric subregion, identifying a material, performing a coordinate remapping, specifying a texture, performing mathematical operations, specifying a color to be displayed within a user interface, or combinations thereof.

Operator 200 receives at least one input, which may include input position 220. As discussed above, an operator may identify a volumetric subregion of an object based on a position within the object, and/or may identify a material composition based on the position. Accordingly, the output 240 of operator 200 may include an identification of the volumetric subregion in which the position is located and/or an identification of a material to be formed in that position. Input position 220 may define a position in any suitable way, and using any suitable coordinate system (e.g., rectilinear, polar, cylindrical, etc.).

As discussed above, operator 200 may be used in a graph (e.g., a directed acyclic graph) such that another operator is executed depending on the output of operator 200. This may be performed in any suitable way, including by producing multiple outputs from operator 200 and associating each with a respective operator, or by selecting another operator to which an output value is sent based on the output value produced by operator 200. For example, operator 200 may be part of a hierarchical design scheme and may decompose an object into two volumetric subregions. The output 240 of the operator may, based on the input position 220, identify another operator within the hierarchical design scheme to execute. The other operator might, for example, identify a material for the position, or perform further decomposition of the identified volumetric subregion based on the position.

Auxiliary data 230 may include any input data provided to operator 200 other than an input position. According to some embodiments, auxiliary data 230 includes one or more attributes associated with an object for which a hierarchical design scheme is being produced. For example, the attributes may include directions of normals defined on the surface of the object. According to some embodiments, auxiliary data 230 may include texture (e.g., UV) coordinates such that positions on (or close to) the surface of an object may be identified as being at a particular point within a texture pattern. This may, for example, allow operator 200 to produce a texture pattern by identifying a texture color or other texture value for a number of input positions, such that the output values for each input position together produce the texture pattern. In some use cases, textures may be procedural in nature and/or may be based on image data, and/or may be defined in two- or three-dimensions. According to some embodiments, auxiliary data 230 may include procedurally generated data such as one or more noise functions (e.g., Worley and/or Perlin noise). By combining texture data with position data, an operator may be configured to produce texture patterns that vary with position in an object (e.g., produce a texture close to the surface but not within the body of an object).

According to some embodiments, auxiliary data 230 may include coordinate transformation data. Operator 200 may perform a remapping of coordinates, for example, and so an input position 220 may be operated upon by coordinate transformation data such that the output includes a position determined in a new coordinate scheme. This may include performing a transformation within the coordinate system of the input position (e.g., transforming a rectilinear coordinate into a new rectilinear coordinate based on a cylindrical transformation) or by performing a transformation into a new coordinate system (e.g., transforming a rectilinear coordinate into a cylindrical coordinate).

According to some embodiments, auxiliary data 230 may include one or more data lookups. In some cases, auxiliary data may include mechanical or other data with which an object is to be designed. For example, an object may be designed to produce a particular mechanical stress profile and this profile may be used by an operator to design aspects of the object, such as by selecting the diameter of a volumetric subregion to vary with position based on the stress profile. In general, any number of data lookups may be provided as a function of position or otherwise with which an operator may determine an output.

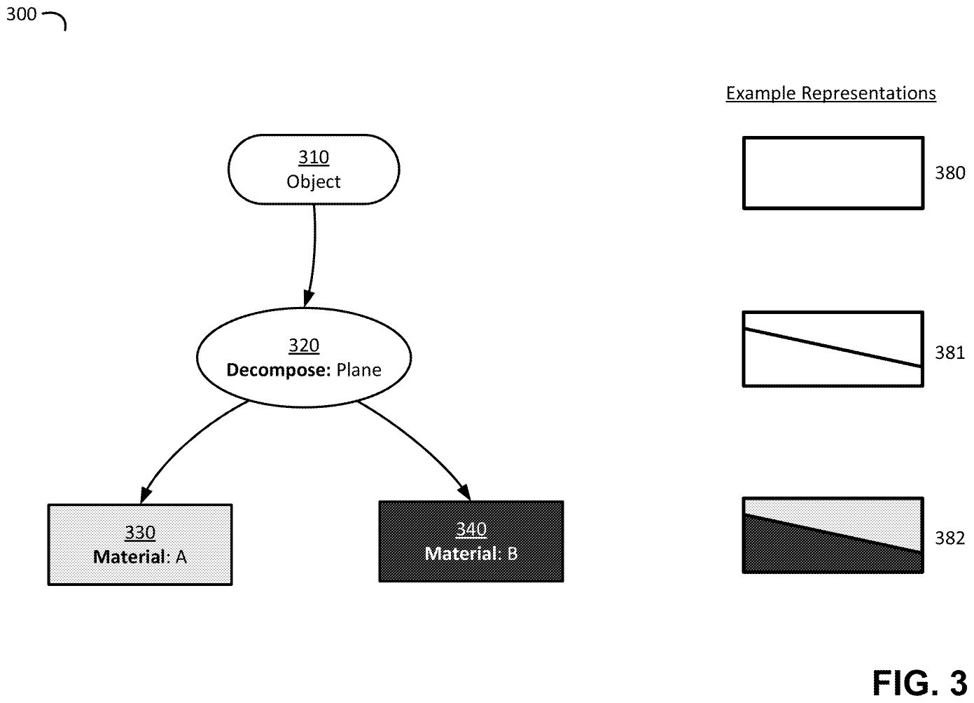

FIG. 3 depicts an illustrative hierarchical design scheme that decomposes an object based on a plane operator, according to some embodiments. Hierarchical design scheme 300 illustrates an example of describing a hierarchical design scheme using a graph structure. Example representations of an object (shown in two dimensions for clarity) produced at various stages of the hierarchical design scheme is depicted in images 380-382.

As discussed above, a hierarchical design scheme may provide a way to decompose an object into subregions and to indicate a material for each identified subregion, thereby designing the composition of the object. FIG. 3 illustrates a simple example in which an object 310 is decomposed based on a plane operator and a material selected for each identified subregion. In hierarchical design scheme 300, object 310 is provided as an input to the hierarchical design scheme, and may comprise any suitable description of an object. In some use cases, object 310 may be a computer file or files that describes the shape of an object (e.g., may be an industry standard 3D object file, such as an STL file). Example representation 380 depicts a rectangle for purposes of illustrating how hierarchical design scheme 300 may be used to design the material composition of an object. The shape depicted may, for example, be a cross-section through a cuboidal object.

Operator 320 performs a decomposition of the input object 310 based on a plane. That is, object 310 is decomposed into two volumetric subregions by diving three-dimensional space into two portions through the plane. Assuming that the plane passes through at least part of object 310, the object will be decomposed into two subregions. The decomposition performed by operator 320 may be specified using any suitable representation, such as by specifying a vector within the plane or normal to the plane (e.g., a unit vector), and a height of the plane. As shown in example representation 381, the illustrative rectangular object is decomposed into two subregions by the plane decomposition operator.

Material composition operators 330 and 340 each is assigned to one of the subregions identified by the spatial decomposition performed by operator 320. Each of the material compositions selected for hierarchical design scheme 300 may be chosen based on available materials for a suitable additive fabrication process, or otherwise. In the example of FIG. 3, both material composition operators 330 and 340 are homogeneous material compositions. As shown in example representation 382, each subregion of the rectangular shape is filled with one of the identified material compositions.

As discussed above, when fabricating an object via additive fabrication, material is formed in a plurality of volume elements, which together form the object. Furthermore, a hierarchical design scheme may determine which is to be formed at each location. Hierarchical design scheme may be used as such in the following way: For a given location in three-dimensional space (e.g., an (x,y,z) coordinate location) that is within the object, the location may be provided to operator 320. The operator 320 may determine on which side of the plane the location is situated. For example, if the plane is described by the equation ax+by+cz+d=0, where a, b, c and d are constants, then by evaluating this equation for an (x,y,z) coordinate location, the sign of the result will indicate on which side of the plane the location is situated. However, in general any suitable way of describing the plane and evaluating on which side of the plane the location is situated (including use of any coordinate system) may be used. Subsequent to this step, either material composition A or B will be chosen by following the branch from operator 320 based on which of the two subregions are identified for the location. Accordingly, a material may be identified for the location in three-dimensional space using hierarchical design scheme 300. An additive fabrication device may then be instructed to form that material in the corresponding location (e.g., at a volume element centered on the coordinate location, at a volume element having a corner at the coordinate location, etc.).

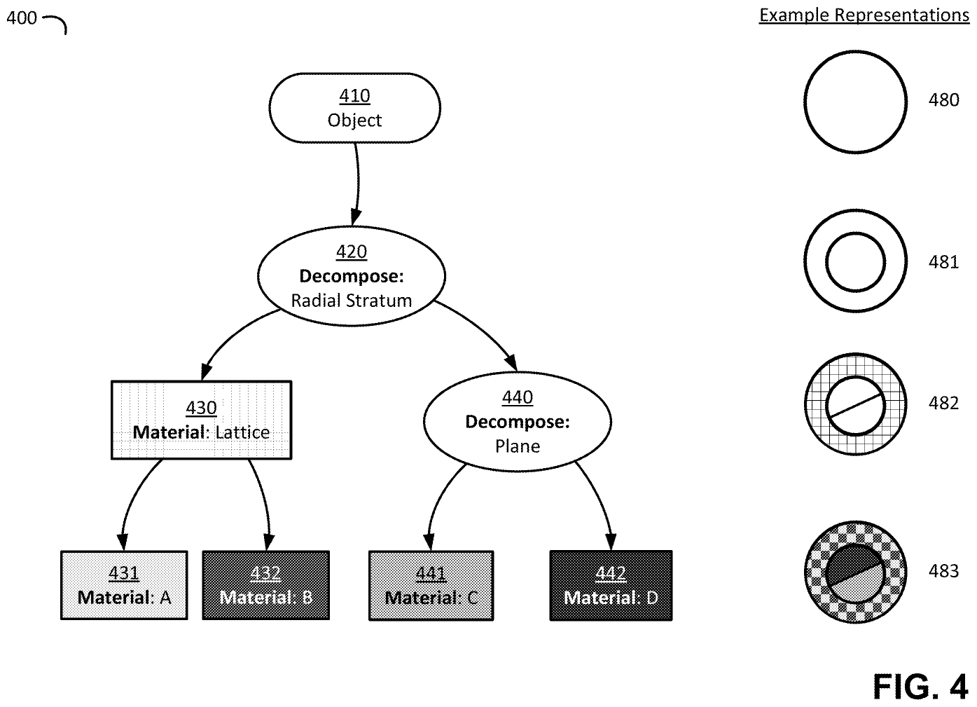

FIG. 4 depicts an illustrative hierarchical design scheme that decomposes an object based on a radial stratum operator, according to some embodiments. As with FIG. 3, hierarchical design scheme 400 shown in FIG. 4 illustrates an example of describing a hierarchical design scheme using a graph structure. An example representation of an object (shown in two dimensions for clarity) is depicted in images 480-483. FIG. 4 illustrates an example in which shape 410 is decomposed based on a radial stratum operator, a material composition is selected for one identified subregion and another identified subregion is further decomposed based on a plane operator.

In hierarchical design scheme 400, object 410 is provided as an input to the hierarchical design scheme, and decomposition operator 420 identifies subregions of the object based on a radial stratum. A radial stratum decomposes a space based on a radial distance from a point, and may use one or more radial distances as thresholds at which to decompose the space. In the example of FIG. 4, example representation 480 depicts a circular shape (e.g., which may be a cross-section through a sphere), which is decomposed into two subregions by operator 420 based on a radial distance from the center of the circular shape (e.g., which may be the center of a sphere). A single radial distance threshold is used in illustrative operator 420, and accordingly the example representation is shown with subregions occupying two regions in the central and outer areas, respectively, of the circular shape.

The outer region identified by the decomposition operator 420 is provided to material composition operator 430, and the inner region provided to decomposition operator 440. Material composition operator 430 is a heterogeneous material composition that is a rectangular lattice comprising two material composition operators 431 and 432 for homogenous materials A and B, respectively. Decomposition operator 440 decomposes the inner region based on a plane, and is associated with homogenous materials C and D in material composition operators 441 and 442, respectively. Accordingly, as shown in example representations 482 and 483, the inner region identified by operator 420 is decomposed into two regions, which are each then filled with a respective homogeneous material composition (materials C and D), whereas the outer region identified by operator 420 is filled with a heterogeneous material composition (the rectangular lattice composition) comprising materials A and B.

As described above, hierarchical design scheme 400 may determine, for a given three-dimension location within object 410, which material should be formed at the location. As with the example of FIG. 3, a coordinate location within the object may be provided to operator 420, which determines whether the location is within the inner or outer region identified by the radial stratum. If the location is in the inner region, the plane operator may be evaluated for the location to determine in which of the two subregions within the inner region the location is situated. If, instead, the location is in the outer region identified by operator 420, the location may be evaluated to determine which cell type the location is in (i.e., which of the two materials fills the cell in which the location is situated). Note that, due to the graph or tree structure of the hierarchical design scheme, only one of material composition operators 430 or 440 may ever be evaluated for a given location. Thus, a material may be identified for a location in a computationally efficient manner.

It will be appreciated that the example representations 480-483 are provided merely to illustrate how hierarchical design scheme 400 may be applied to a simple shape. In general, hierarchical design scheme may be applied to any object having any shape. Further, illustrative hierarchical design scheme 400 may be described any number of suitable parameters. As a non-limiting example, the following parameters may be used: a center location and radial threshold for operator 420; a cell size and origin location for material composition operator 430; a normal vector and height for plane operator 440; and an indication of materials 431, 432, 441 and 442.

Once hierarchical design scheme 400 has been defined, a user may adjust any number of these parameters as desired. The user may, for example, adjust the cell size of the rectangular lattice used in material composition operator 430 and evaluate whether the new cell size is more preferable for the design at hand than the previous cell size. It may therefore be beneficial for a user to develop a hierarchical design scheme in an environment where visual feedback is provided to a user as the hierarchical design scheme is generated and/or modified.

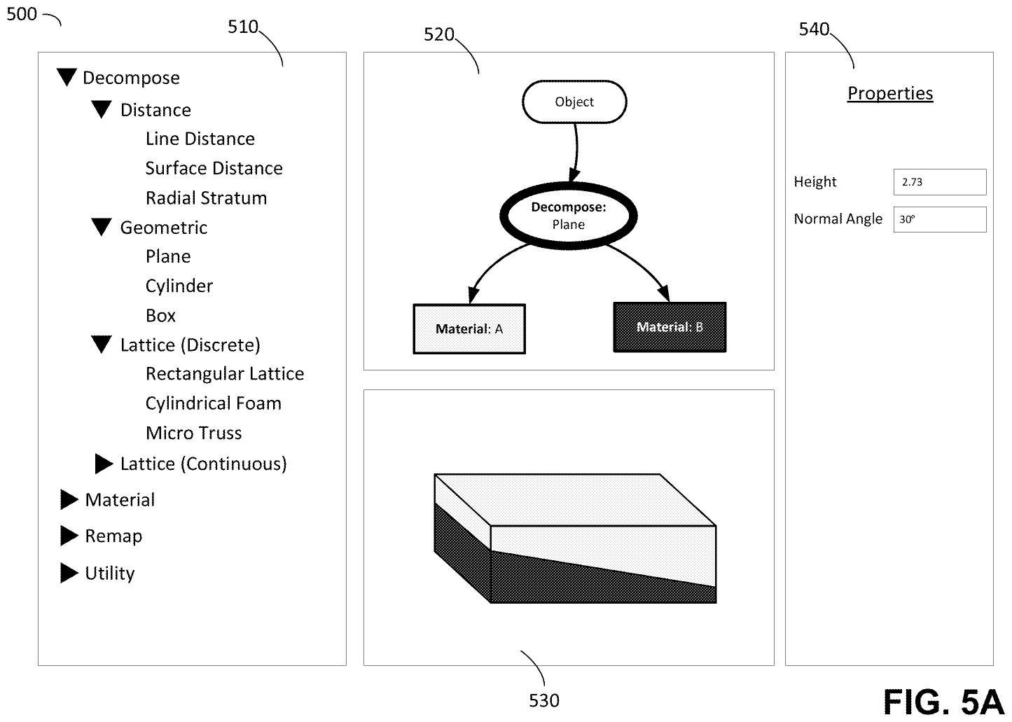

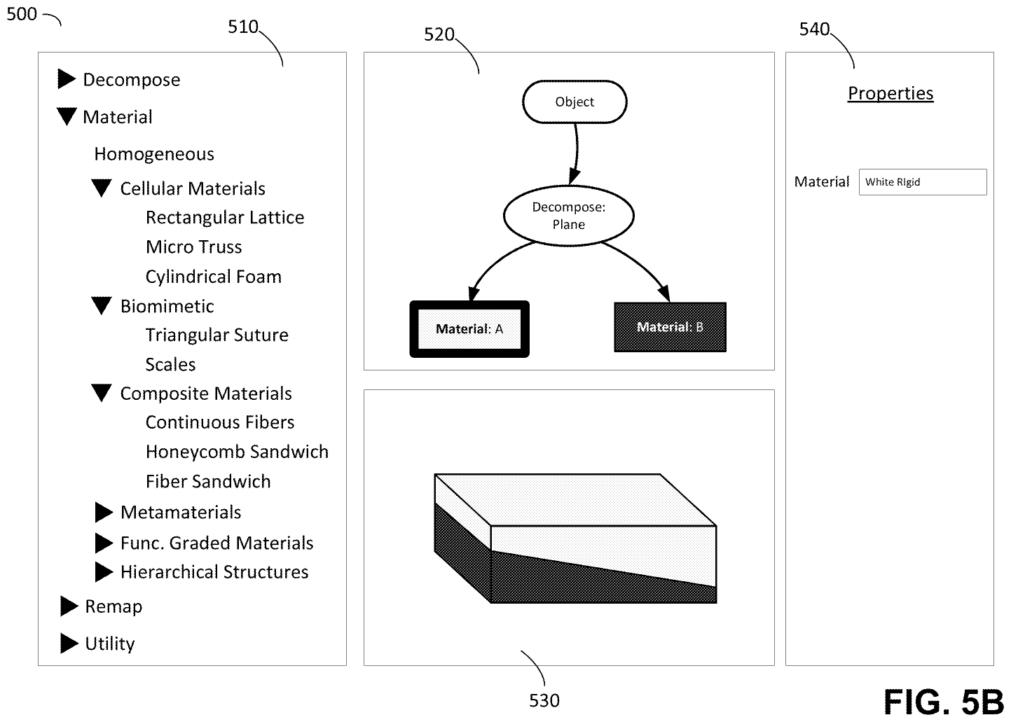

FIGS. 5A-B depict one such graphical user interface suitable for generation and/or modification of a hierarchical design scheme, according to some embodiments. Graphical User Interface (GUI) 500 includes operator selection area 510, in which various types of operators that may be added to a hierarchical design scheme are provided for selection by a user. Examples of the provided operators are discussed below. GUI 500 also includes a display of the hierarchical design scheme being developed 520, a list of properties of a selected operator of the hierarchical design scheme 540, and a three-dimensional representation of the material composition of the object being designed 530. In the example of FIG. 5A, hierarchical design scheme 300 depicted in FIG. 3 is shown as an example in display area 520, wherein the plane decomposition operator is currently selected (denoted in the figure by a thick border) and properties of this operator are shown in property list 540.

In the example of FIGS. 5A-B, as a user adjusts properties of an operator in the hierarchical design scheme shown in display area 520, adds or removes operators to the hierarchical design scheme by selecting them from the operator selection area 510 (e.g., by clicking and dragging), and/or adds, modifies and/or deletes connections between operators in the hierarchical design scheme (e.g., by dragging connection points from one operator to another), the three-dimensional representation of the object 530 may be updated in real-time or otherwise so that the user can see the effects of their actions to the object being designed. This may allow a user to efficiently produce a hierarchical design scheme that produces a desired result on an object by providing visual feedback on adjustments to the hierarchical design scheme.

FIG. 5A depicts a number of illustrative decomposition operators in operator selection area 510, in addition to material operators, remap operators and utility operators. Decomposition operators, as discussed above, decompose a space into multiple subregions. These are organized, in the example of FIG. 5A, into distance, geometric, discrete lattice and continuous lattice decomposition operators. Distance decomposition operators decompose a space based on a distance function, and include the radial stratum operator discussed above in relation to FIG. 4, in addition to a line distance operator, which decomposes based on a distance from a set of curves, and a surface distance operator, which decomposes based on a distance from a surface. Any distance decomposition operator may decompose a space into any number of subregions by utilizing multiple distance threshold values to delineate the subregions. It will be appreciated that these illustrative operators are provided merely as examples, as other decompositions based on one or more distances may be envisioned.

Decomposition operators shown in operator selection area 510 also include geometric decomposition operators, which decompose a space using a geometric primitive such that a subregion is identified on one side of the primitive boundary and another subregion is identified on another side of the primitive boundary. For example, as discussed above, a plane may be used to decompose a space into two subregions. In addition, illustrative geometrical decomposition operators shown in FIG. 5A include a cylinder-based decomposition which decomposes a space into two subregions being either inside or outside of the cylinder, and include a box-based decomposition which decomposes a space into subregions being either inside or outside of the box. It will be appreciated that these illustrative operators are provided merely as examples, as other decompositions based on a geometrical primitive (e.g., a cone, sphere, paraboloid, non-uniform rational B-spline (NURB), etc.) may be envisioned.

Decomposition operators shown in operator selection area 510 also include discrete and continuous lattice operators, which decompose a space into uniform grids and/or tilings. The grids and tilings may be based on any shape and any suitable coordinate system. For example, a grid may be rectangular, hexagonal, tetrahedral, etc. and a tiling may be hexahedral, tetrahedral, etc. Where a grid is applied to a three-dimensional volume, the grid pattern is projected as a two-dimensional grid through the volume (e.g., a hexagonal grid may produce a number of hexagonal prisms). For the purposes of applying further decomposition(s) or applying material compositions to the subregions identified by a grid or tile-based decomposition, the subregions may be grouped in any suitable way such that groups of subregions may be targeted by operators. The difference between the discrete and continuous lattice operators in the example of FIG. 5A is that discrete operators decompose a space into lattice cells in addition to subregions at the borders of the lattice cells (e.g., decompose into lattice cell subregions in addition to subregions defined by lattice edges and/or lattice vertices), whereas continuous operators decompose a space into the lattice cell subregions only (though may still separate the lattice cells based on lattice edges and/or lattice vertices). In some use cases, lattice vertex and edge thicknesses may be adjustable parameters of a lattice decomposition operator, in addition to the size of the lattice cells.

Illustrative lattice decomposition operators shown in FIG. 5A include a rectangular lattice decomposition operator, which decomposes a space into a plurality of cuboid-shaped cells, and a cylindrical foam decomposition operator, which decomposes a space into cylindrical cells. In some use cases, the cylindrical foam operator may define one or more radii of cylinders within each cylindrical cell or otherwise define the size of the thickness of the cell edges. Illustrative lattice decomposition operators shown in FIG. 5A also includes a micro truss decomposition operator which decomposes a space into a truss-shaped subregion and a non-truss subregion. In some use cases, the micro truss decomposition operator may by defined by a length, height and a radius of the truss subregion.

FIG. 5B depicts the same GUI 500 as shown in FIG. 5A, but with a different selection of operators shown in operator selection area 510. In particular, operators that define material compositions are shown, as described in further detail below. In addition, a material composition operator for material A has been selected in display area 520, and this operator's properties are shown in property list 540.

Material composition operators, as discussed above, define a homogeneous or heterogeneous material for an object or for an identified subregion of an object. These are, in the example of FIG. 5B, organized into cellular, biomimetic, composite, metamaterial, functionally graded and hierarchical material composition operators. Each of these types of material composition operators are heterogeneous material composition operators. FIG. 5B also includes a homogeneous material composition operator in operator selection area 510.

Material composition operators shown in operator selection area 510 include cellular material composition operators, which define materials having regular lattice topology or irregular foam structures, such as honeycomb, pyramidal, tetrahedral, or 3D-Kagome lattice truss structures. These materials may include open-cell-structure foams (where pores of the foam are connected to one another) as well as closed-cell-foams. Cellular materials may typically have a comparatively low density (since most of the space may be not filled with material). Illustrative cellular material composition operators shown in FIG. 5B include a rectangular lattice, in which materials are organized into a plurality of cuboid-shaped cells, a micro truss, in which material is formed in a truss-shape, and cylindrical foam, in which material is formed into cylinders (and/or formed around cylinders).

Material composition operators shown in operator selection area 510 also include biomimetic material composition operators, which are materials that draw inspiration from nature. Typically, a spatial arrangement of constituent materials are copied through the structure, while the constituent materials may be copied and/or replaced. Non-limiting examples of biomimetic materials include honeycomb structures, wood fibers and bone structures. Illustrative biomimetic material composition operators shown in FIG. 5B include a triangular suture, in which interlocking seams tie stiffer components together, and scales, in which material is layered in a similar manner to fish scales.

Material composition operators shown in operator selection area 510 also include composite material composition operators, which define materials made from two or more constituent materials, where at least one material forms a matrix and at least one material provides reinforcement. The reinforcement material(s) add rigidity to the structure and the matrix material(s) surround them. Composite materials typically have one or more properties different from those of any of the constituent materials. Non-limiting examples of composite materials include concrete (loose stones held with a matrix of cement), plywood and bone. Composite materials may include sandwich-structured composites formed by sandwiching a comparatively thick and light core material between two comparatively thin and stiff materials. Illustrative composite material composition operators shown in FIG. 5B include continuous fibers, in which fibers are formed in a matrix, a honeycomb sandwich, in which a honeycomb structure is sandwiches with sheets, and a fiber sandwich, in which fibers are sandwiched by multiple sheets.

Material composition operators shown in operator selection area 510 also include metamaterial material composition operators, which define cellular-like structures, which are typically periodic. These structures may exhibit mechanical, optical, acoustic and/or electromagnetic properties that cannot be produced by materials that are found in nature. The properties may result from the material structure rather than properties of the constituent materials. Non-limiting examples of metamaterials include materials with a negative Poisson's ratio (that expand when stretched), pentamode metamaterials/meta-fluids (solid materials that are comparatively easy to deform but comparatively hard to compress), and materials with a negative refractive index.

Material composition operators shown in operator selection area 510 also include functionally graded material composition operators, which define a material where the composition and/or structure of one or more constituent materials may gradually change over the volume. For example, a material composition may gradually change (e.g., linearly) from material A at one side of a volume to material B at the other side.

Material composition operators shown in operator selection area 510 also include hierarchical structure material composition operators, which define materials that have structure defined at different scales of the object. Such a structure has defined features at multiple scales, and can result in improved mechanical properties over the constituent material(s).

It may be noted that some of the material composition operators have a similar structure to certain decomposition operators. For example, the rectangular lattice decomposition and rectangular lattice material composition operators both may be used to define material in a rectangular lattice. In some use cases, it may be beneficial to have access to both types of operator for convenience when developing a hierarchical design scheme. For example, a rectangular lattice decomposition operator may identify a number of subregions of a space, which may be preferred when one or more of those subregions is to be further decomposed. In contrast, a rectangular lattice material composition operator fills a designated space with one or more materials, which may be preferred when each of the rectangular lattice cells is to be filled with a homogenous material. However, in general either or both such operators could be used in similar ways, though both may be provided for convenience to a user.

Operator selection area 510 also includes a group of remap operators, although no illustrative examples are shown in FIG. 5B. A remap operator remaps a space into a different coordinate system. Where it may be beneficial for an operator to act on a space using a different coordinate system than is otherwise used, the remap operator may be applied to remap the coordinate system of the operator. For example, operators in a hierarchical design scheme may be based on a rectilinear (Cartesian) coordinate system, but in some aspects of the design scheme it may be beneficial to instead use a different coordinate system.

In some use cases, decomposition operators and/or material composition operators that define a repeating pattern may be particularly suited for such a coordinate transformation. For example, when defining a cylindrical foam material for the exterior of a sphere, it may be desired that the cylinders propagate radially outwards from the center of the sphere. In a rectilinear coordinate system, a cylindrical foam decomposition operator or material composition operator may produce parallel cylinders that would not produce the desired result. Accordingly, the cylindrical foam decomposition operator may have a remap operator applied to it to convert the coordinate system from a rectilinear system to a system of spherical coordinates before the cylindrical features are determined. A non-limiting list of suitable remap operators includes spherical to rectilinear, rectilinear to spherical, cylindrical to rectilinear and/or rectilinear to cylindrical.

As discussed above, a hierarchical design scheme may indicate, for a location of a volume element in an object, which material is to be formed at that location. Typically, therefore, the default coordinate system of a hierarchical design scheme will be that of the additive fabrication device being used. While many additive fabrication devices are based on a rectilinear coordinate system, others may utilize a polar coordinate system. Irrespective of the default coordinate system chosen for a hierarchical design scheme, remap operators may be used to remap the coordinate system into another coordinate system for any number of operators in the scheme. The coordinate of the volume element being evaluated by the hierarchical design scheme may, for example, be linearly transformed within that coordinate system so that it may be evaluated and return to the additive fabrication device in its native coordinate system.

Operator selection area 510 also includes a group of utility operators which may perform additional operations within a hierarchical design scheme. Utility operators may include operators that apply complex patterns to a subregion, such as procedural and/or image-based texture definitions. For example, an image texture utility operator may apply a pattern to a subregion based on a two-dimensional image file; a marble utility operator may apply a procedural marble pattern to a subregion. Such a utility operator may specify two or more material compositions with which to form the texture in addition to an orientation of the texture in space. In some use cases, UV texture coordinates may be supplied for the purposes of mapping a texture to a subregion via a utility operator.

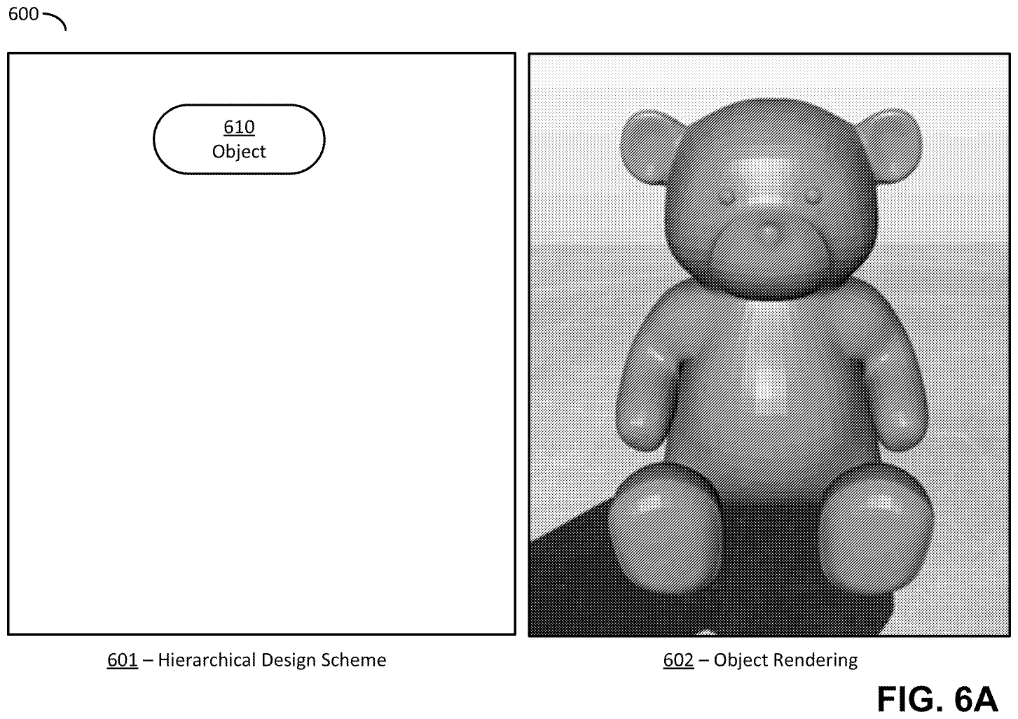

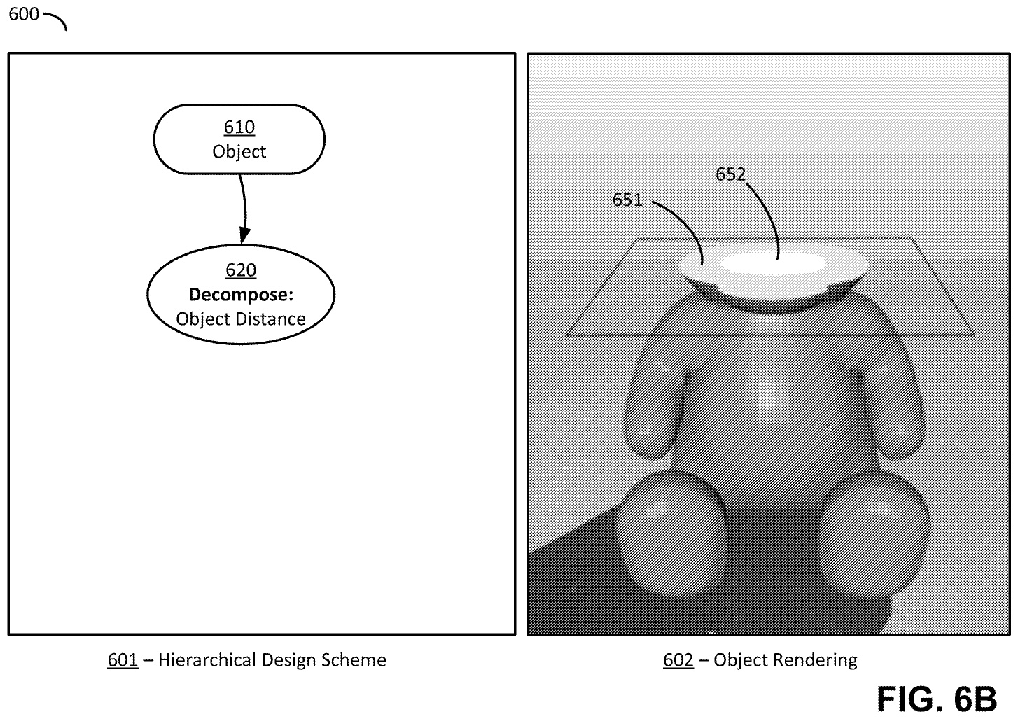

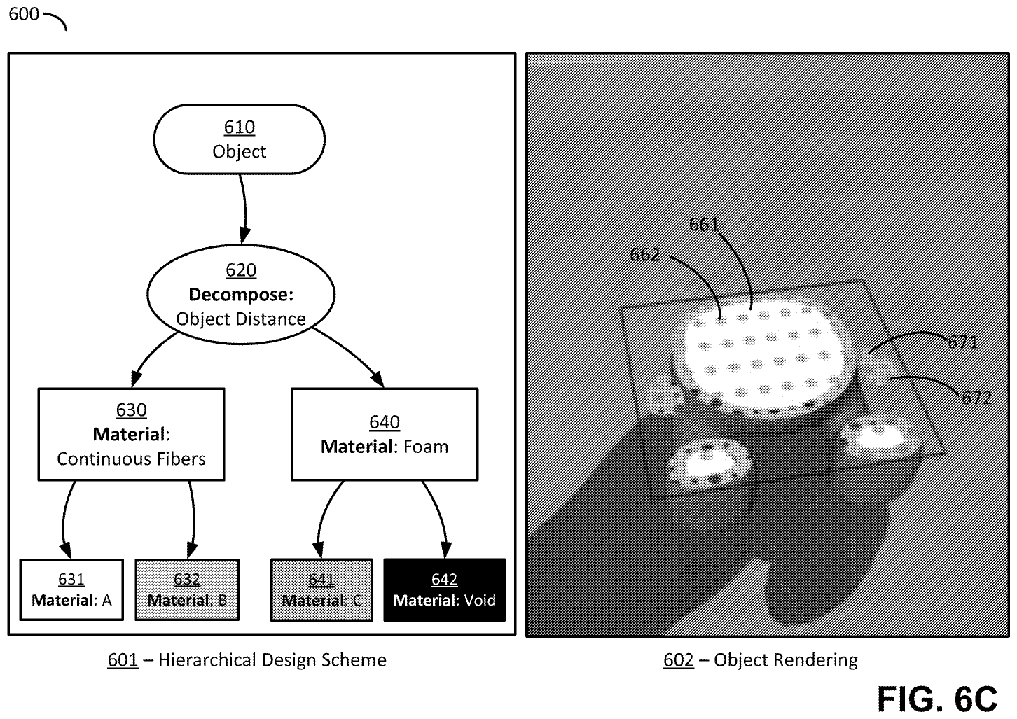

FIGS. 6A-C depict steps of an illustrative process in which the material composition of a teddy bear is designed using a hierarchical design scheme, according to some embodiments. In FIGS. 6A-C, graphical user interface 600 includes a display of hierarchical design scheme 601, which is designed by the process depicted in FIGS. 6A-C, and an object rendering 602 of the object being designed. The object rendering 602, in the examples of FIGS. 6A-C is used to provide feedback to a user as to how the hierarchical design scheme being designed is applied to the object.

In FIG. 6A, the teddy bear object to be designed has been added as a root element 610 of the hierarchical design scheme 601 and is shown as object rendering 602. In FIG. 6A, no operators that decompose, define material compositions, or otherwise perform noticeable effects on the root object 610 have been added. Accordingly, the object rendering 602 simply depicts the object's shape (a teddy bear) without modification. In some use cases, a graphical user interface (GUI) being used to produce a hierarchical design scheme may provide tools to rotate the rendering of the object and/or to perform slices through the object so that a user can view the interior and/or exterior of the object during the design process. The illustrative GUI shown in FIGS. 6A-C includes such tools, as depicted in FIGS. 6B-C.

In FIG. 6B, a decomposition operator 620 has been added to the hierarchical design scheme that performs a decomposition of the root object 610. Decomposition operator 620 is based on a distance to the surface of the object, and decomposes the object into a subregion at the exterior (adjacent to the surface) of the object and a subregion in the interior. This decomposition to exterior and interior subregions is shown in the object rendering by labeled subregions 651 and 652, respectively. As described above, the illustrative GUI of FIG. 6B includes tools to perform slices through the object, and accordingly the object rendering 602 shown in FIG. 6B shows a slice through the object so that a cross section through the subregions identified by the decomposition operator 620 may be viewed. Tools may be provided in a GUI so that a user may adjust the position and/or orientation of such a slice to inspect various aspects of the object.

In FIG. 6C, two heterogeneous material composition operators, 630 and 640, have been added to the interior and exterior subregions, respectively, identified by decomposition operator 620. Material composition operator 630 creates continuous fibers through the interior of the volume which, as shown in the object rendering 602, are oriented along the vertical axis of the object. The cylinders are composed of material B via operator 632 and the remainder of the subregion is composed of material A via operator 631. Material composition operator 640 defines a foam in the exterior subregion identified by decomposition operator 620. The foam is composed of void regions via operator 642 within the remaining regions composed of material C via operator 641.

The resulting object, as designed by the hierarchical design scheme shown in FIG. 6C, may have a “spongy” feel due to the foam producing empty regions of space in the exterior of the object. If material C is relatively compressible, this may further increase the ability of the object to be compressed under force. The interior of the object may have a rigid structure provided by the fibers of material B, while material A may fill out the interior subregion with a less dense material than material B, thus providing a strong structure with a low overall density.

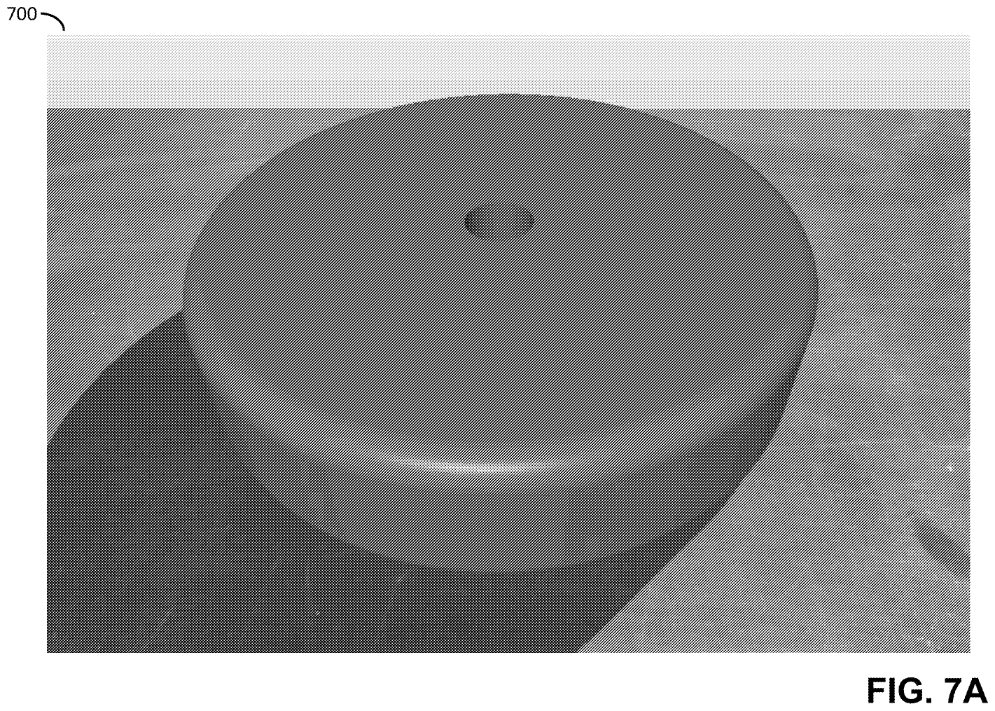

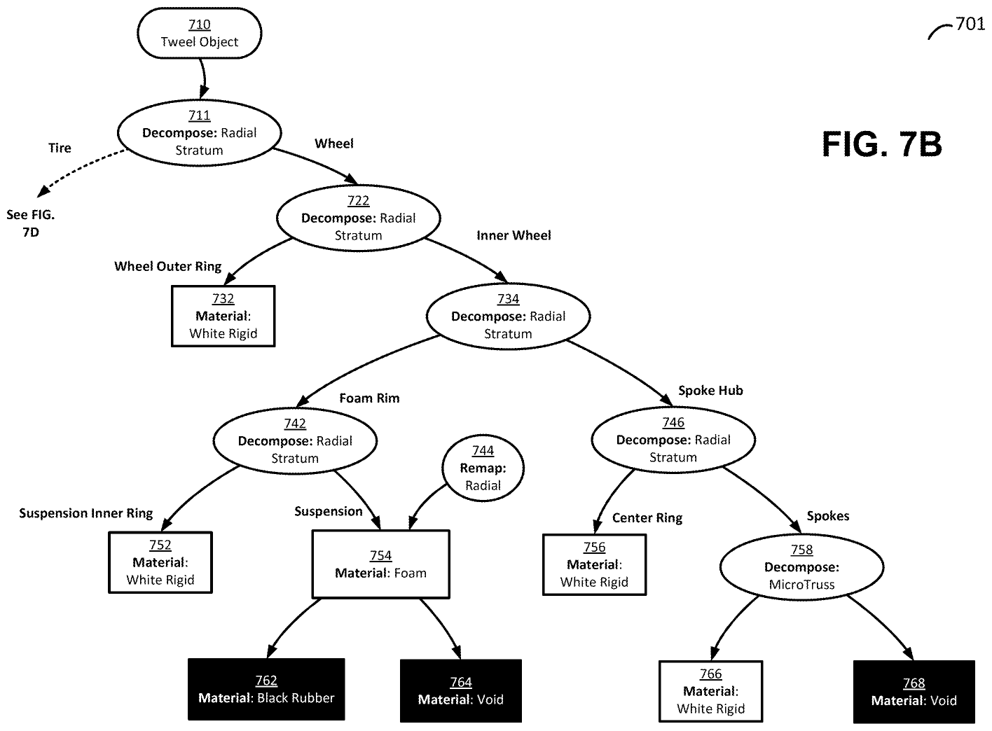

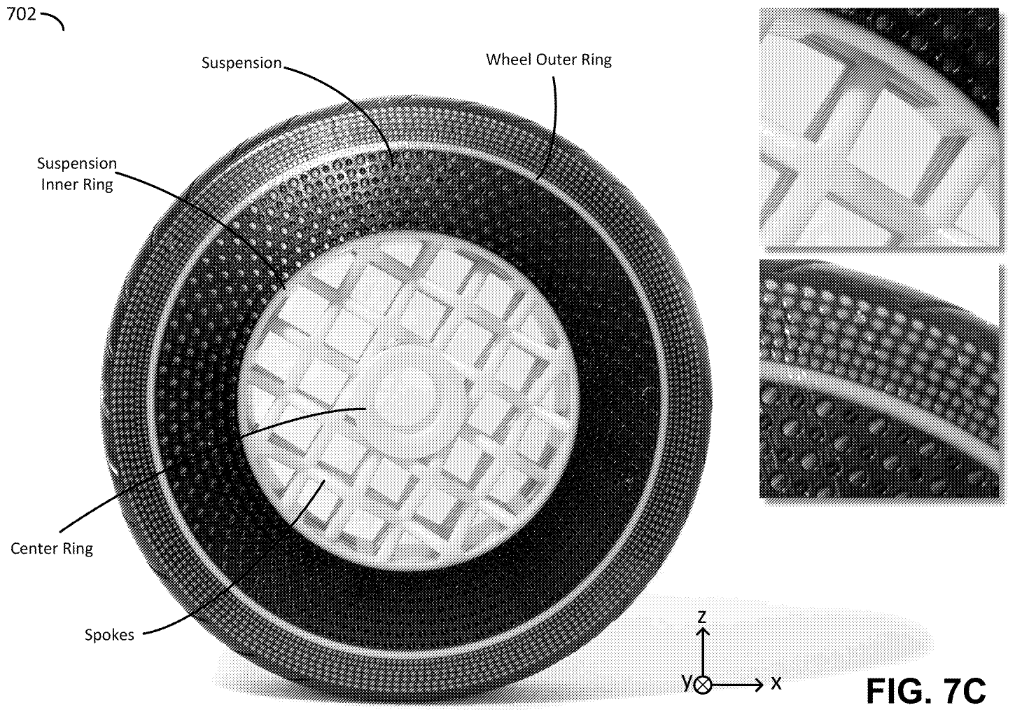

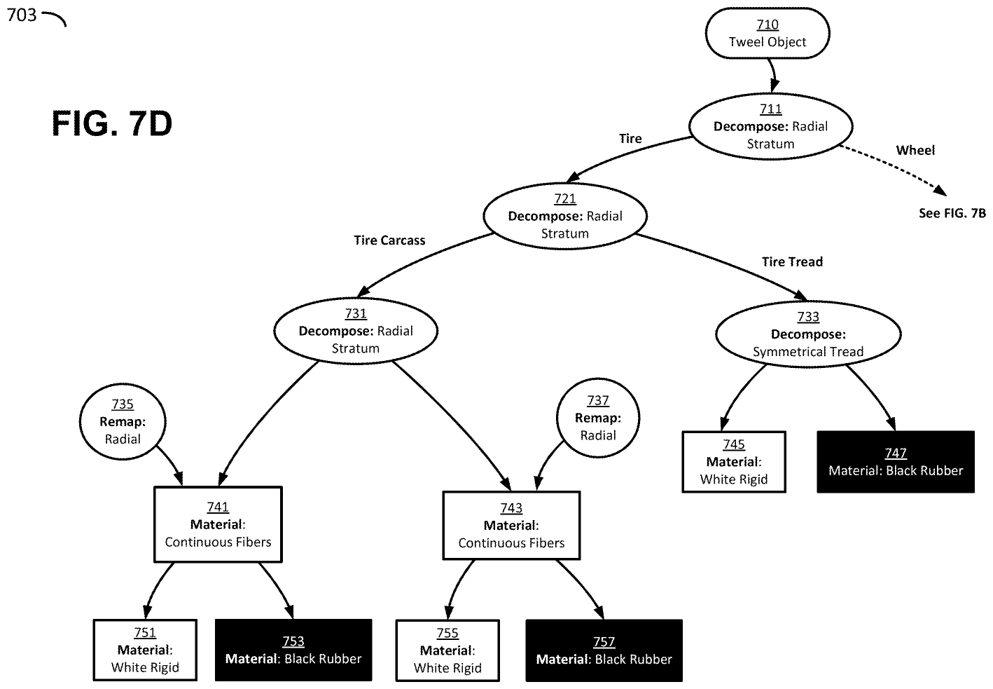

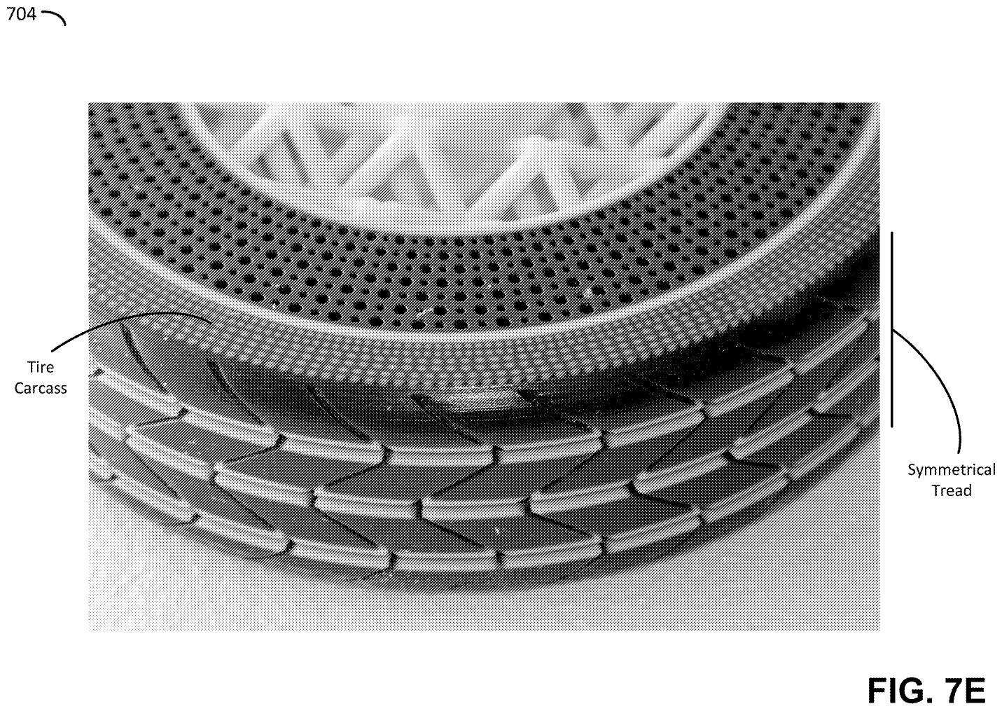

FIGS. 7A-E illustrate aspects of a “tweel” object designed by a hierarchical design scheme, according to some embodiments. A tweel is an object that foregoes the traditional pneumatic design of a tire plus a wheel and instead combines the tire and wheel into a single unit. A tweel is both puncture free, since there is no separate air-filled tire, and includes suspension capabilities. In the example of FIGS. 7A-E, a tweel is designed using techniques described herein using from a toroidal shape, depicted in FIG. 7A. Various subregions of this shape are defined, and material compositions selected, such that the tweel object may be produced as a single object having desired appearance and properties.

The illustrative tweel uses a hierarchical design scheme, of which part is shown in FIG. 7B. In particular, aspects of the tweel hierarchical design scheme shown in FIG. 7B include those aspects that define the material composition of the interior of the tweel, whereas aspects that define the exterior of the tweel are shown in FIG. 7D. The tweel object 710, being the shape depicted in FIG. 7A, is decomposed into inner and outer subregions via a radial stratum decomposition operator 711. The inner subregion is used to define the wheel of the tweel via the remaining operators shown in FIG. 7B, and the outer subregion is used to define the tire of the tweel via the operators shown in FIG. 7D. Subregions identified by decomposition operators in FIGS. 7B and 7D are denoted by named labels in the figure, some of which are labeled on photographs of a tweel shown in FIGS. 7C and 7E that was fabricated via the illustrative hierarchical design scheme.

The radial stratum decomposition operator 711, along with the other radial stratum decomposition operators shown in FIGS. 7B and 7D, use the center of the toroidal object 710 as an origin and measure distance radially outwards along the radial axis of the object for purposes of measuring distance for the decomposition. Hence, the outer subregion used to define the tire of the tweel, as shown in FIG. 7D, is that subregion of the shape that has a distance along the radial axis exceeding a cutoff value. The outer subregion thereby has a shape of a toroid having a rectangular cross-section with one dimension of the cross-section being the thickness of the shape in the radial direction from the cutoff radius to the boundary of the shape, and the other dimension of the cross-section being the thickness of the tweel in the y-direction as shown by the axes in FIG. 7C. The inner subregion is the remainder of the object, being another toroid having a rectangular cross-section.

With regards to FIGS. 7B and 7C, radial stratum decomposition operator 722 separates the inner subregion of the tweel into an exterior “wheel outer ring” subregion, which is filled with a white rigid material 732 and an interior “inner wheel” subregion. The inner wheel subregion is decomposed by radial stratum decomposition operator 734 into an exterior “foam rim” subregion and an interior “spoke hub” subregion. The foam rim subregion is decomposed by radial stratum decomposition operator 742 into an interior “suspension inner ring” subregion, which is filled with the white rigid material 752, and an exterior “suspension” subregion, both of which are shown in FIG. 7C. The suspension subregion is filled with a foam material via material composition operator 754 which defines a repeating pattern of two different sizes of holes that pass through the subregion parallel to the y-axis. So that the hole pattern propagates radially (e.g., in concentric rings of holes when viewed along the y-axis, rather than in rectangular rows of holes), a radial remap operator 744 is applied to the foam material composition operator 754. As discussed above, the remap operator may perform a coordinate transformation such that holes are formed in the intended radial locations. The holes are filled with a void material 764 (i.e., do not contain any formed material) and the remainder of the foam structure is filled with a black rubber material 762.

The spoke hub subregion identified by decomposition operator 734 is further decomposed by radial stratum decomposition operator 746. An interior center ring subregion is identified and filled with the white rigid material 756 and the remaining exterior subregion is further decomposed via a microtruss decomposition operator 758. The microtruss creates the spoke shapes toward the center of the tweel by filling the truss shape identified by the microtruss decomposition operator 758 with the white rigid material, and by filling the remainder of the subregion with the void material.

As described above, the portion of the hierarchical design scheme shown in FIG. 7B thereby defines the material composition of the interior of the tweel being the volume within, and including, the wheel outer ring shown in FIG. 7C. Similarly, the remainder of the tweel is defined by the portion of the hierarchical design scheme shown in FIG. 7D. In FIG. 7D, the tire subregion identified as the exterior subregion of radial stratum decomposition operator 711 is further decomposed by radial stratum decomposition operator 721 into an exterior “tire tread” subregion and an interior “tire carcass” subregion. The tire tread subregion, which is at the surface of the object, has the symmetrical tread material composition operator 733 applied to it, which defines the pattern of grooves and black and white materials shown in FIG. 7E.

The tire carcass subregion identified by decomposition operator 721 is further decomposed by radial stratum decomposition operator 731 into an exterior subregion and an interior subregion, both of which are filled with a continuous fiber material composition comprising the white rigid material (in 751 and 755, respectively) and the black rubber material (in 753 and 757, respectively). As can be seen in FIG. 7E, the two continuous fiber subregions of the tire carcass utilize different fiber diameters, with the inner subregion having a smaller fiber diameter. In addition, both material composition operators 741 and 743 have a radial remap operator applied so that the fiber patterns propagates radially from the center of the tweel.

As may be seen from the example of FIGS. 7A-E, a material object having numerous physical characteristics (e.g., tire grip, suspension, a rigid frame, etc.) may be designed and fabricated using the techniques described herein. In the case of the particular tweel shown in FIGS. 7A-E, the object may be fabricated from only two different fabrication materials (the white rigid and black rubber materials). Accordingly, any additive fabrication device able to fabricate an object from such suitable materials may be used to produce a physical tweel object, based on the described hierarchical design scheme so defined for the tweel. In addition, a tweel of any size may be produced using the same hierarchical design scheme, although scales of features such as foam and/or fiber material compositions may be adjusted as desired based on the new size. It will be appreciated that the same input object, shown in FIG. 7A, may be used to produce a suitable hierarchical design scheme for a tweel based on any number of suitable approaches which used any number of materials, and that the particular hierarchical design scheme shown in FIGS. 7B and 7D is provided merely as an illustrative example.

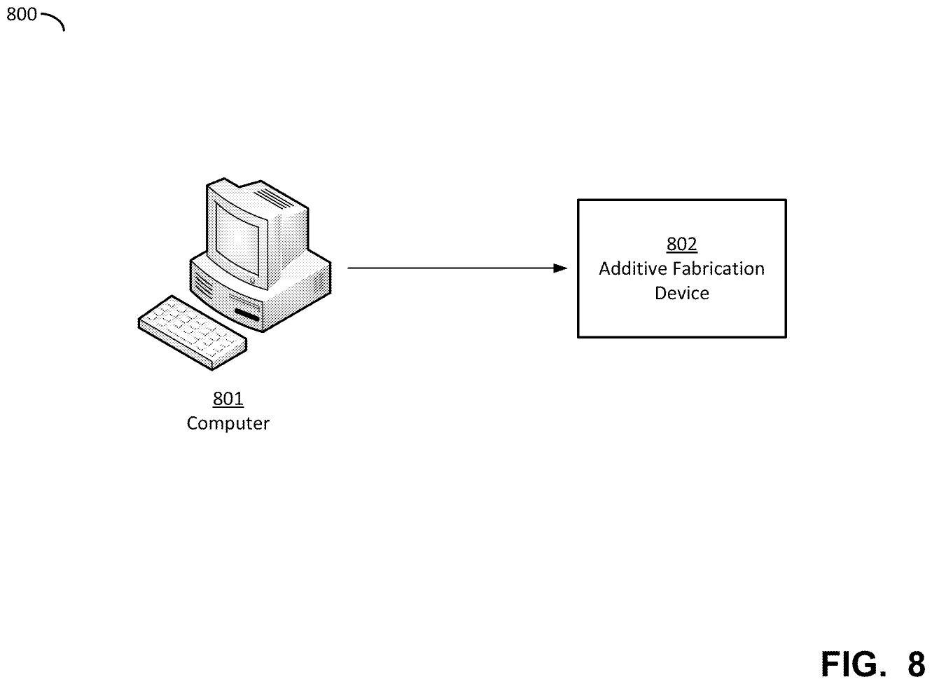

FIG. 8 depicts a system suitable for practicing aspects of the invention, according to some embodiments. As discussed above, there are a number of use cases in which a hierarchical design scheme (such as hierarchical design schemes 300 or 400 shown in FIGS. 3 and 4, respectively) may be defined by a user. In some cases, a hierarchical design scheme may be defined, in whole or in part, by a user without direct access to an additive fabrication device. The user may, for example, define a hierarchical design scheme and provide the hierarchical design scheme to a third party who may use an additive fabrication device to fabricate an object according to the hierarchical design scheme. In some cases, a user may define a hierarchical design scheme and determine a material for each volume element of an object via the hierarchical design scheme, then provide an indication of the determined materials to a third party, who may fabricated the object according to the indications.

In some use cases, a user who defines a hierarchical design scheme may also perform fabrication of an object using an additive fabrication device according to the hierarchical design scheme (e.g., once a material for each volume element of the object has been determined according to the hierarchical design scheme). In some use cases, an additive fabrication device may begin formation of an object once a material has been determined according to a hierarchical design scheme for only a subset of volume elements of the object.

FIG. 8 illustrates system 800, which includes computer 801 and additive fabrication device 802. System 800 may be suitable for use in cases where a hierarchical design scheme is designed by (or obtained by) computer 801 and an object is fabricated according to the hierarchical design scheme using additive fabrication device 802 (e.g., by providing indications of materials for each volume element of the object to the additive fabrication device). In addition, or alternatively, system 800 may be suitable for use in cases where computer 801 receives an indication of materials to be used to form volume elements of an object and instructs additive fabrication device 802 to fabricate the object according to the indications.

The additive fabrication device 802 may begin fabrication of an object based on any number of indications of material for volume elements of an object. In some cases, the additive fabrication device may receive indications of material for all volume elements of an object before beginning fabrication. In other cases, once indications of material have been received for a suitable subset of volume elements of an object (e.g., volume elements to be fabricated first), the additive fabrication may begin fabrication. For example, indications of materials for a subset of elements may be determined by computer 801 according to available memory of the additive fabrication device 802, and further subsets may be provided periodically to the additive fabrication device as the device forms volume elements and accordingly may have information regarding those volume elements that may be deleted from memory in order to generate free memory to receive additional data.

According to some embodiments, computer 801 may perform method 100 shown in FIG. 1 for some or all of the volume elements in an object, and may do so in serial (i.e., perform method 100 for each volume elements one by one) or may do so at least partially in parallel (i.e., perform method 100 for at least two volume elements simultaneously).

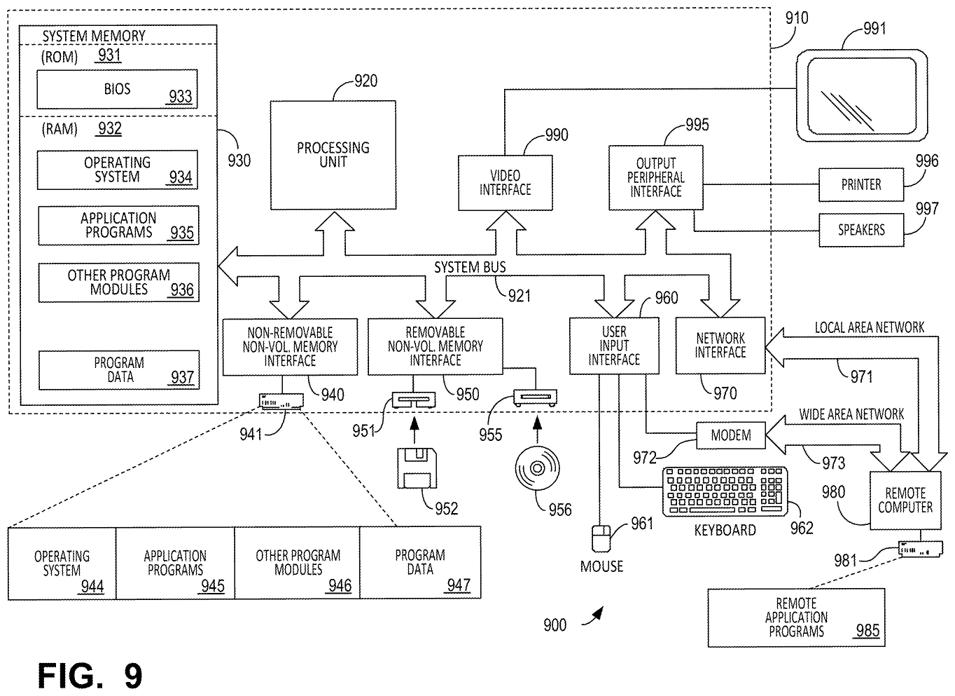

FIG. 9 illustrates an example of a suitable computing system environment 900 on which aspects of the invention may be implemented. For example, the computing system environment 900 may be used to define a hierarchical design scheme, to determine a material for one or more volume elements of an object according to a hierarchical design scheme (e.g., perform method 100 shown in FIG. 1), direct an additive fabrication device to fabricate an object according to a hierarchical design scheme, may act as computer 801 shown in FIG. 8, or any combinations thereof. Such a computing environment may represent a home computer, a tablet, a mobile device, a server and/or any another computing device.

The computing system environment 900 is only one example of a suitable computing environment and is not intended to suggest any limitation as to the scope of use or functionality of the invention. Neither should the computing environment 900 be interpreted as having any dependency or requirement relating to any one or combination of components illustrated in the exemplary operating environment 900.

Aspects of the invention are operational with numerous other general purpose or special purpose computing system environments or configurations. Examples of well-known computing systems, environments, and/or configurations that may be suitable for use with the invention include, but are not limited to, personal computers, server computers, hand-held or laptop devices, multiprocessor systems, microprocessor-based systems, set top boxes, programmable consumer electronics, network PCs, minicomputers, mainframe computers, distributed computing environments that include any of the above systems or devices, and the like.

The computing environment 900 may execute computer-executable instructions, such as program modules. Generally, program modules include routines, programs, objects, components, data structures, etc. that perform particular tasks or implement particular abstract data types. The invention may also be practiced in distributed computing environments where tasks are performed by remote processing devices that are linked through a communications network. In a distributed computing environment, program modules may be located in both local and remote computer storage media including memory storage devices.

With reference to FIG. 9, an illustrative system for implementing aspects of the invention includes a general purpose computing device in the form of a computer 910. Components of computer 910 may include, but are not limited to, a processing unit 920, a system memory 930, and a system bus 921 that couples various system components including the system memory to the processing unit 920. The system bus 921 may be any of several types of bus structures including a memory bus or memory controller, a peripheral bus, and a local bus using any of a variety of bus architectures. By way of example, and not limitation, such architectures may include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus also known as Mezzanine bus.

Computer 910 typically includes a variety of computer readable media. Computer readable media can be any available media that can be accessed by computer 910 and includes both volatile and nonvolatile media, removable and non-removable media. By way of example, and not limitation, computer readable media may comprise computer storage media and communication media. Computer storage media includes both volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, Digital Versatile Disks (DVD), Blu-ray, or other optical disk storage, magnetic cassettes, magnetic tape, magnetic disk storage or other magnetic storage devices, or any other medium which can be used to store the desired information and which can accessed by computer 910. Communication media typically embodies computer readable instructions, data structures, program modules or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer readable media.

The system memory 930 includes computer storage media in the form of volatile and/or nonvolatile memory such as read only memory (ROM) 931 and/or random access memory (RAM) 932. A basic input/output system 933 (BIOS), containing routines that help to transfer information between elements within computer 910, such as during start-up, is typically stored in ROM 931. RAM 932 typically contains data and/or program modules that are immediately accessible to and/or presently being operated on by processing unit 920. By way of example, and not limitation, FIG. 9 illustrates operating system 934, application programs 935, other program modules 936, and program data 937.

The computer 910 may also include other removable/non-removable, volatile/nonvolatile computer storage media. By way of example only, FIG. 9 illustrates a hard disk drive 941 that reads from and/or writes to non-removable, nonvolatile magnetic media, a magnetic disk drive 951 that reads from and/or writes to a removable, nonvolatile magnetic disk 952, and an optical disk drive 955 that reads from and/or writes to a removable, nonvolatile optical disk 956 such as a CD ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM, and the like. The hard disk drive 941 is typically connected to the system bus 921 through an non-removable memory interface such as interface 940, and magnetic disk drive 951 and optical disk drive 955 are typically connected to the system bus 921 by a removable memory interface, such as interface 950.

The drives and their associated computer storage media discussed above and illustrated in FIG. 9 provide storage of computer readable instructions, data structures, program modules and/or other data for computer 910. In FIG. 9, for example, hard disk drive 941 is illustrated as storing operating system 944, application programs 945, other program modules 946, and program data 947. These components may be the same as or different from operating system 934, application programs 935, other program modules 936, and program data 937. Operating system 944, application programs 945, other program modules 946, and program data 947 are given different numbers here to illustrate that, at a minimum, they are different copies. A user may enter commands and information into the computer 910 through input devices such as a keyboard 962 and pointing device 961, commonly referred to as a mouse, trackball or touch pad. Other input devices (not shown) may include a microphone, joystick, game pad, satellite dish, scanner, or the like. These and other input devices are often connected to the processing unit 920 through a user input interface 960 that is coupled to the system bus, but may be connected by other interface and bus structures, such as a parallel port, game port or a universal serial bus (USB). A monitor 991 or other type of display device is also connected to the system bus 921 via an interface, such as a video interface 990. In addition to the monitor, computers may also include other peripheral output devices such as speakers 997 and printer 996, which may be connected through a output peripheral interface 995.

The computer 910 may operate in a networked environment using logical connections to one or more remote computers, such as a remote computer 980. The remote computer 980 may be a personal computer, a server, a router, a network PC, a peer device or other common network node, and typically includes many or all of the elements described above relative to the computer 910, although only a memory storage device 981 has been illustrated in FIG. 9. The logical connections depicted in FIG. 9 include a local area network (LAN) 971 and a wide area network (WAN) 973, but may also include other networks. Such networking environments are commonplace in offices, enterprise-wide computer networks, intranets and the Internet.

When used in a LAN networking environment, the computer 910 is connected to the LAN 971 through a network interface or adapter 970. When used in a WAN networking environment, the computer 910 typically includes a modem 972 or other means for establishing communications over the WAN 973, such as the Internet. The modem 972, which may be internal or external, may be connected to the system bus 921 via the user input interface 960, and/or via another appropriate mechanism. In a networked environment, program modules depicted relative to the computer 910, or portions thereof, may be stored in the remote memory storage device. By way of example, and not limitation, FIG. 9 illustrates remote application programs 985 as residing on memory device 981. It will be appreciated that the network connections shown are exemplary and other means of establishing a communications link between the computers may be used.

The various methods or processes outlined herein may be implemented in any suitable hardware. Additionally, the various methods or processes outlined herein may be implemented in a combination of hardware and of software executable on one or more processors that employ any one of a variety of operating systems or platforms. For example, the various methods or processes may utilize software to instruct a processor to determine a material for a volume element of an object according to a hierarchical design scheme. Example of such approaches are described above. However, any suitable combination of hardware and software may be employed to realize any of the embodiments discussed herein.

According to some embodiments, the techniques described herein, including those of defining one or more operators, may be implemented using a suitable domain specific programming language. Use of a domain specific language may provide several advantages over a general purpose language for the methods or processes outlined herein. For example, a domain specific language may allow production of a hierarchical design scheme that is extensible, performant and robust. In some cases, a domain specific language may simplify implementation of operators and/or hierarchical design schemes, since the language may be written with such objects in mind. In some cases, implementing aspects of the invention such as operators using a domain specific language may produce results more quickly (e.g., may compile and/or execute quicker) than a general purpose language because the language may be optimized for the particular task (e.g., determination of a material for a volume element of an object). Finally, in some cases it may be easier to execute a hierarchical design scheme in a sandbox fashion when using a domain specific language, thus simplifying development for a user, providing robust execution and reducing support and maintenance requirements by the system provider.

In this respect, various inventive concepts may be embodied as at least one non-transitory computer readable storage medium (e.g., a computer memory, one or more floppy discs, compact discs, optical discs, magnetic tapes, flash memories, circuit configurations in Field Programmable Gate Arrays or other semiconductor devices, etc.) encoded with one or more programs that, when executed on one or more computers or other processors, implement the various embodiments of the present invention. The non-transitory computer-readable medium or media may be transportable, such that the program or programs stored thereon may be loaded onto any computer resource to implement various aspects of the present invention as discussed above.

The terms “program” or “software” are used herein in a generic sense to refer to any type of computer code or set of computer-executable instructions that can be employed to program a computer or other processor to implement various aspects of embodiments as discussed above. Additionally, it should be appreciated that according to one aspect, one or more computer programs that when executed perform methods of the present invention need not reside on a single computer or processor, but may be distributed in a modular fashion among different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically, the functionality of the program modules may be combined or distributed as desired in various embodiments.

Having herein described several embodiments, several advantages of embodiments of the present application should be apparent. A non-limiting list of applications for which embodiments described herein may be used include optics, mechanical engineering, industrial design, aerospace design, musical instruments, toys and games, and combinations thereof.

Various inputs to the design of a three-dimensional object have been discussed above, and it will be appreciated that any number of inputs may be considered in designing an object using the techniques described herein. A non-limiting list of suitable inputs may include an input shape (e.g., a geometrical object), one or more materials from which the object may be fabricated, one or more properties of the one or more materials (e.g., mechanical properties, cost, weight/density, thermal properties, electrical properties, etc.), details on a fabrication technique (e.g., specifications of an additive fabrication system, such as a resolution; time to fabrication based on an object composition), or combinations thereof.

Various inventive concepts may be embodied as one or more methods, of which examples have been provided. The acts performed as part of any method described herein may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein, unless clearly indicated to the contrary, should be understood to mean “at least one.”

As used herein, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.”

The phraseology and terminology used herein is for the purpose of description and should not be regarded as limiting. The use of “including,” “comprising,” “having,” “containing”, “involving”, and variations thereof, is meant to encompass the items listed thereafter and additional items.

Having described several embodiments of the invention in detail, various modifications and improvements will readily occur to those skilled in the art. Such modifications and improvements are intended to be within the spirit and scope of the invention. Accordingly, the foregoing description is by way of example only, and is not intended as limiting.

What is claimed is:

1-24. (canceled)

25. A method for forming a hierarchical specification of an object for controlling a three-dimensional printer in fabricating said object, the method comprising:
accepting a first object specification, said first object specification specifying a volume of the object;
providing a graphical user interface to a user for interactively forming the hierarchical specification; and
providing the hierarchical specification for use in fabricating the object;
wherein the graphical user interface is configured to perform functions including:
(a) accepting a specification of a volumetric decomposition operator from the user, said operator defining at least two subregions of the volume of the object;
(b) accepting a specification of a material composition operator for a subregion of the object;
(c) provide a three-dimensional rendering of the object to the user indicating a plurality of subregions resulting from one or more volumetric decompositions; and
(d) providing a display of a hierarchical design scheme to the user resulting from multiple volumetric decomposition specification accepted from the user;
wherein the hierarchical specification includes specifications of one or more volumetric decomposition operators and of one or more material composition operators, and a hierarchy of subregions for use in controlling the three-dimensional printer to fabricate the object.

26. The method of claim 25, wherein accepting the specification of the volumetric decomposition includes accepting a specification of a type of decomposition, and specification of one or more parameters for that type of decomposition.

27. The method of claim 26, wherein a choice or multiple types of decomposition is solicited from the user via the user interface.

28. The method of claim 26, wherein the type of decomposition comprises a type of distance-based operator.

29. The method of claim 28, wherein the distance-based operator is specified by parameters defining at least one of a plane, a point, and a curve in the volume of the object.

30. The method of claim 25, wherein the material composition operator for the subregion comprises a heterogeneous material composition operator.

31. The method of claim 30, wherein the heterogeneous material composition operator defines for all locations in the subregion a material composition for that location, the material composition varying over the subregion.

32. The method of claim 31, wherein the accepting the specification of the material composition operator includes accepting a specification of a type of material composition operation.

33. The method of claim 32, wherein the type of material composition operation comprises at least one a cellular, biomimetic, composite, metamaterial, functionally graded, and hierarchical material composition operator.
